(19) United States
(12) Patent Application Publication
(10) Pub. No.: US 2018/0341160 A1
(43) Pub. Date: Nov. 29, 2018

(54) DISPLAY DEVICE AND DISPLAY PANEL WITH NOVEL PIXEL AND DATA LINE CONFIGURATIONS

(71) Applicant: InnoLux Corporation, Miao-Li County (TW)

(72) Inventors: Yu-Jhou GONG, Miao-Li County (TW); Yao-Lien HSIEH, Miao-Li County (TW); Chung-Yi WANG, Miao-Li County (TW); Li-Wei SUNG, Miao-Li County (TW)

(21) Appl. No.: 15/984,546

(22) Filed: May 21, 2018

(30) Foreign Application Priority Data
May 23, 2017 (CN) 201710368967.9

(51) Int. Cl. G02F 1/1362; G09G 3/36; H01L 27/12

(52) U.S. Cl. CPC G02F 1/136286; G09G 3/3688; G09G 3/3614; G09G 3/3607; G02F 2001/13606; G09G 2300/0426; G09G 2320/0209; G09G 2320/0219; H01L 27/124

(57) ABSTRACT

A display panel includes a pixel array with pixel cells and multiple data lines coupled to the pixel array. The multiple pixel cells include multiple first pixel cells and multiple second pixel cells. The multiple data lines include multiple first data lines and multiple second data lines. One of the multiple first data lines is coupled to the multiple first pixel cells in the pixel array. The multiple second data lines include a third data line and a fourth data line adjacent to the third data line. A part of the multiple second pixel cells coupled to the third data line and another part of the multiple second pixel cells coupled to the fourth data line are configured to display the same color.

### CROSS REFERENCE TO RELATED APPLICATIONS

This Application claims priority of China Patent Application No. 201710368967.9, filed on May 23, 2017, the entirety of which is incorporated by reference herein.

### BACKGROUND

### Field of the Disclosure

The disclosure relates to a display panel, and more particularly to a display panel with novel pixel and data line configurations.

### Description of the Related Art

An organic light-emitting diode (OLED) display, a liquid-crystal display (LCD), a micro-LED display and a quantum dot display are the three mainstream types of modern displays. With any display type, however, as long as the video signal is written into the display cells in different columns via multiple data lines, crosstalk may occur due to the capacitive coupling effect, which affects the quality of the displayed image.

Therefore, in order to solve the crosstalk problem, a novel display panel design, which is capable of solving the crosstalk problem via the novel pixel and data line configurations, is required.

### BRIEF SUMMARY OF THE DISCLOSURE

A display panel is provided. An exemplary embodiment of a display panel comprises a pixel array and multiple data lines. The pixel array comprises multiple pixel cells. The data lines are coupled to the pixel array. The multiple pixel cells comprise multiple first pixel cells and multiple second pixel cells. The multiple data lines comprise multiple first data lines and multiple second data lines. One of the multiple first data lines is coupled to the multiple first pixel cells in the pixel array. The multiple second data lines comprise a third data line and a fourth data line adjacent to the third data line, wherein a part of the multiple second pixel cells coupled to the third data line and another part of the multiple second pixel cells coupled to the fourth data line are configured to display the same color.

An exemplary embodiment of a display device comprises a display panel and a data driving circuit. The display panel comprises a pixel array and multiple data lines coupled to the pixel array. The data driving circuit is configured to generate multiple data driving signals to provide image data to the pixel array via the multiple data lines. The pixel array comprises multiple pixel cells. The multiple pixel cells comprise multiple first pixel cells and multiple second pixel cells. The multiple data lines comprise multiple first data lines and multiple second data lines. One of the multiple first data lines is coupled to the multiple first pixel cells in the pixel array. The multiple second data lines comprise a third data line and a fourth data line adjacent to the third data line, wherein a part of the multiple second pixel cells coupled to the third data line and another part of the multiple second pixel cells coupled to the fourth data line are configured to display the same color.

A detailed description is given in the following embodiments with reference to the accompanying drawings.

### BRIEF DESCRIPTION OF DRAWINGS

The disclosure can be more fully understood by reading the subsequent detailed description and examples with references made to the accompanying drawings, wherein:

FIG. 1 is a block diagram of a display device according to an embodiment of the disclosure;

FIG. 2 is an exemplary diagram showing the configurations of the pixel cells and the data lines on the display panel according to an embodiment of the disclosure;

FIG. 3A shows the exemplary pixel cell arrangement according to a first embodiment of the disclosure;

FIG. 3B is a schematic diagram showing the voltage polarity of the image data signal to be provided to each pixel cell according to a first embodiment of the disclosure;

FIG. 4A is a schematic diagram showing the minimum array unit according to the first embodiment of the disclosure;

FIG. 4B is a schematic diagram showing the coupling relationship of the data lines and the pixel cells in the active area of the display panel and the output pins of the data driver chip according to the first embodiment of the disclosure;

FIG. 5A shows the exemplary pixel cell arrangement according to a second embodiment of the disclosure;

FIG. 5B is a schematic diagram showing the voltage polarity of the image data signal to be provided to each pixel cell according to a second embodiment of the disclosure;

FIG. 6A shows the exemplary pixel cell arrangement according to a third embodiment of the disclosure;

FIG. 6B is a schematic diagram showing the voltage polarity of the image data signal to be provided to each pixel cell according to a third embodiment of the disclosure;

FIG. 7A shows the exemplary pixel cell arrangement according to a fourth embodiment of the disclosure;

FIG. 7B is a schematic diagram showing the voltage polarity of the image data signal to be provided to each pixel cell according to a fourth embodiment of the disclosure;

FIG. 8A shows the exemplary pixel cell arrangement according to a fifth embodiment of the disclosure; and

FIG. 8B is a schematic diagram showing the voltage polarity of the image data signal to be provided to each pixel cell according to a fifth embodiment of the disclosure.

### DETAILED DESCRIPTION OF THE DISCLOSURE

The following description is of the contemplated mode of carrying out the disclosure. This description is made for the purpose of illustrating the general principles of the disclosure and should not be taken in a limiting sense. The scope of the disclosure is determined by reference to the appended claims.

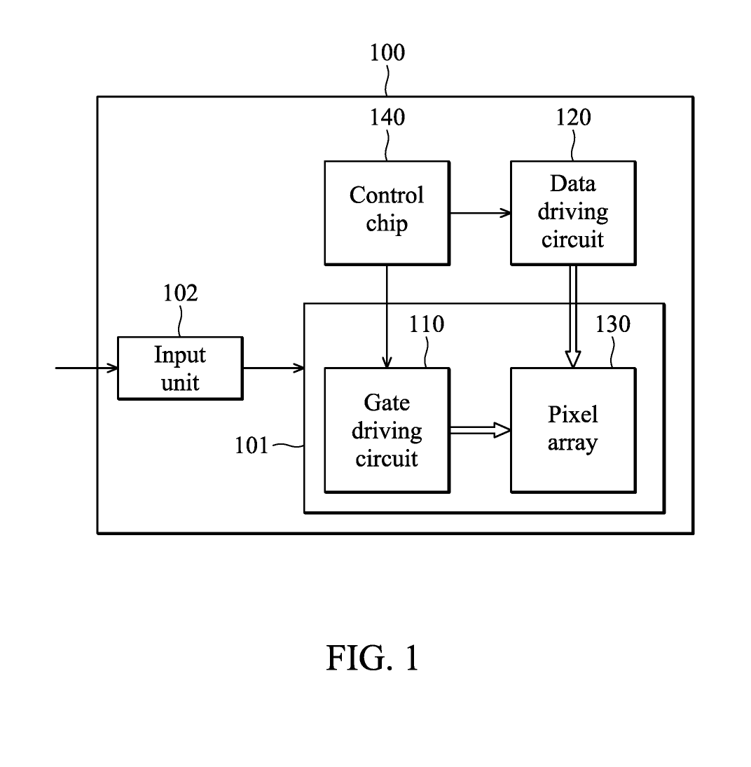

FIG. 1 is a block diagram of a display device according to an embodiment of the disclosure. As shown in FIG. 1, the display device 100 may comprise a display panel 101, a data driving circuit 120 and a control chip 140. The display panel 101 may comprise a gate driving circuit 110 and a pixel array 130. The gate driving circuit 110 generates a plurality of gate driving signals to drive a plurality of pixels in the pixel array 130. The data driving circuit 120 generates a plurality of data driving signals to provide image data to the pixels of the pixel array 130. The control chip 140 generates a plurality of timing signals, comprising clock signals, reset signals and start pulses. It should be noted that the display panel 101 may be a flexible display panel, an LCD display panel, an OLED display panel, a micro-LED display panel or a quantum dot display panel.

In addition, the display device 100 may further comprise an input unit 102. The input unit 102 receives image signals and controls the display panel 101 to display images. According to an embodiment of the disclosure, the display device 100 may further be comprised in an electronic device. The electronic device may be implemented as various devices, comprising: a mobile phone, a digital camera, a laptop computer, a personal computer, a television, an in-vehicle display, a portable DVD player, or any apparatus with image display functionality.

According to an embodiment of the disclosure, as shown in FIG. 1, the gate driving circuit 110 is disposed outside of the pixel array 130, but the disclosure should not be limited thereto. In other embodiments of the disclosure, the gate driving circuit 110 may also be disposed on the pixel array 130. Similarly, although in FIG. 1, the gate driving circuit 110 is disposed on the display panel 101, the disclosure should not be limited thereto. In other embodiments of the disclosure, the gate driving circuit 110 may also be not disposed on the display panel 101.

According to an embodiment of the disclosure, the pixel array 130 may comprise multiple pixel cells. For a color display, the pixel cell may correspond to a single sub-pixel, such as a red (R), blue (B) or green (G) sub-pixel, and one set of the RGB sub-pixels can form a single pixel. In other embodiments, the pixel cell may further correspond to a white (W) sub-pixel, and one set of the RGBW sub-pixels can form a single pixel. In the embodiments of the disclosure, the pixel cell may comprise a transistor and a pixel electrode coupled to the transistor. The sub-pixel may comprise a color filter layer. For example, the red sub-pixel may comprise a red filter layer, the green sub-pixel may comprise a green filter layer, and the blue sub-pixel may comprise a blue filter layer. In a specific type of quantum dot display, the sub-pixel may further comprise a quantum dot layer in addition to the color filter layers. A red pixel cell represents that the pixel cell corresponds to a red sub-pixel, and so on.

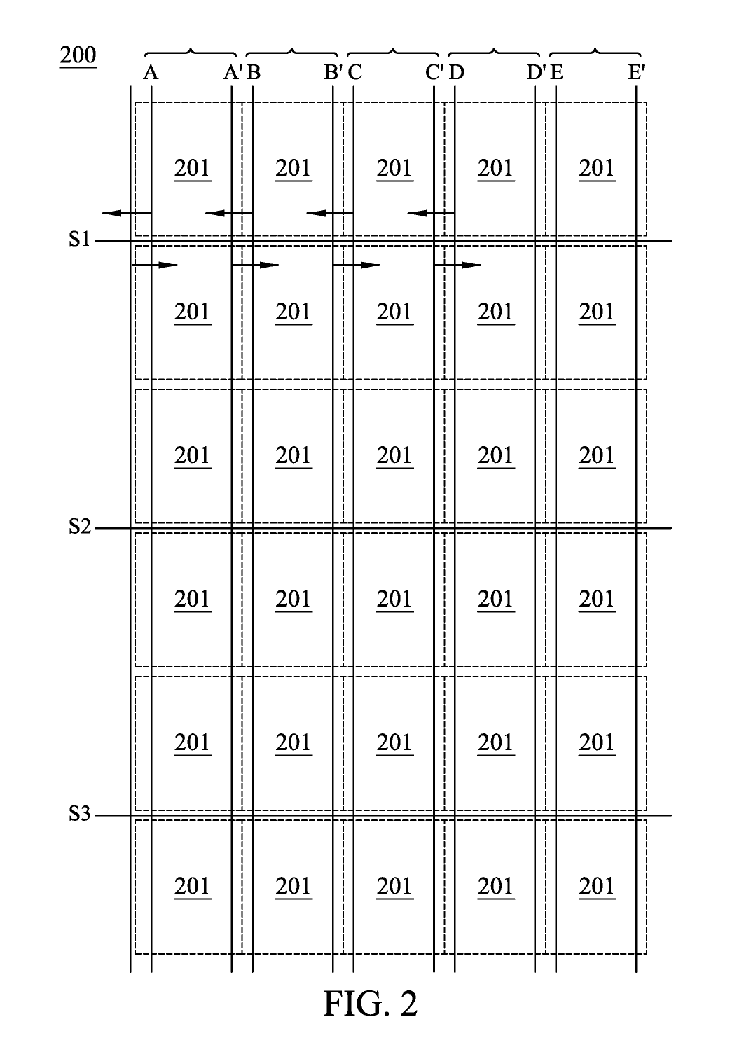

FIG. 2 is an exemplary diagram showing the configurations of the pixel cells and the data lines on the display panel according to an embodiment of the disclosure. According to an embodiment of the disclosure, the display panel 200 may comprise multiple pixel cells 201 which form a pixel array, multiple data lines, such as the data lines A, A′, B, B′, C, C′, D, D′, E and E′, and a plurality of scan lines, such as the scan lines S1, S2 and S3. According to an embodiment of the disclosure, the data lines A, A′, B, B′, C, C′, D, D′, E and E′ are respectively coupled to multiple pixel cells 201, for providing image data to the corresponding pixel cells 201. It should be noted that in the embodiment of the disclosure, each pixel cell is coupled to one data line and one scan line. In addition, in other embodiments of the disclosure, there may be one scan line disposed between every two rows of pixel cells. Therefore, two rows of pixel cells may share one scan line, but the disclosure should not be limited thereto.

The data lines may comprise a plurality of pairs of adjacent data lines. For example, the data lines A and A′ in FIG. 2 may be regarded as a pair of adjacent data lines, the data lines B and B′ in FIG. 2 may be regarded as a pair of adjacent data lines, and so on. According to an embodiment of the disclosure, each pair of adjacent data line may be coupled to the pixel cells configured to display the same color, for providing the image data to the corresponding pixel cells. For example, the data lines A and A′ are both coupled to the red sub-pixels, the data lines B and B′ are both coupled to the green sub-pixels, the data lines C and C′ are both coupled to the blue sub-pixels, and so on. It should be noted that the concept of configuring the pixel cells and the data lines is also applicable for the display panel using four primary colors or the display panel not using the three primary colors. It should be also noted that in the embodiments of the disclosure, the pixel cells configured to display the same color represents that those pixel cells are corresponding to the sub-pixels configured to display the same color, such as the red sub-pixels, the green sub-pixels, or the blue sub-pixels. In addition, the pixel cells may be configured to display different gray scale colors according to different image data.

According to an embodiment of the disclosure, a pair of adjacent data lines are configured to provide image data having opposite voltage polarities. The voltage polarity represents the polarity (that is, positive or negative) of voltage difference between the image data and the common voltage VCOM. For example, a pair of adjacent data lines in each bracket in the figure provides the image data with opposite voltage polarities.

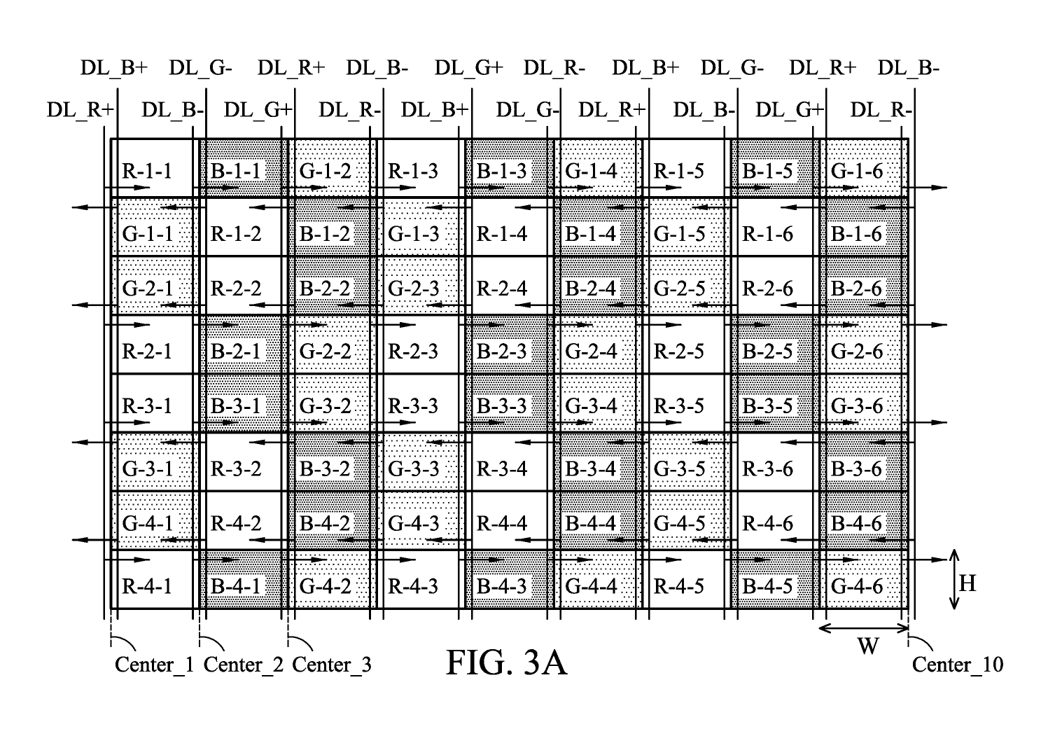

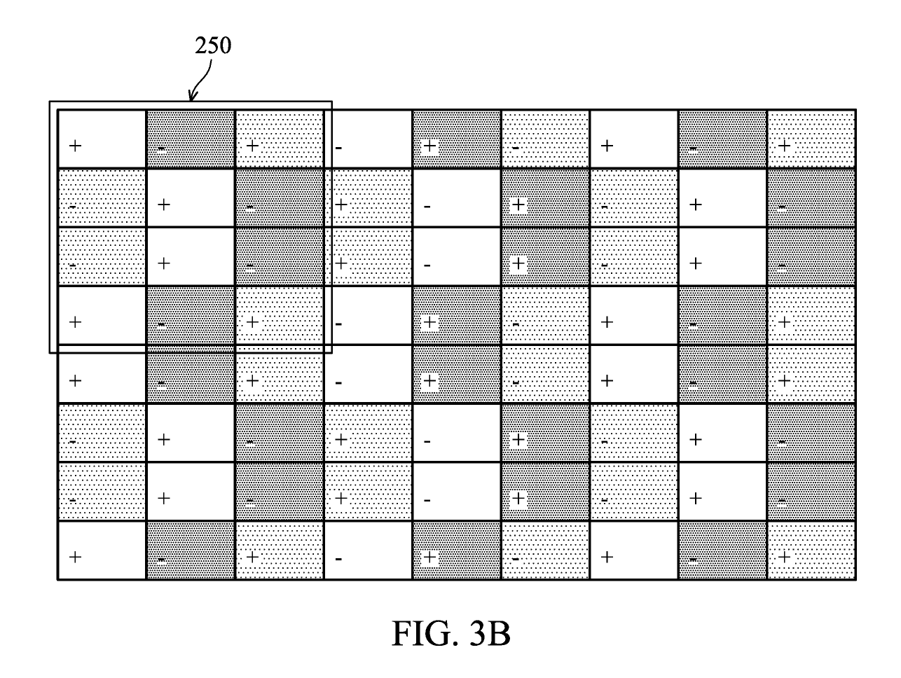

In addition, according to an embodiment of the disclosure, there may be at least two data lines disposed between two adjacent pixel cells or two adjacent columns of pixel cells. For example, at least the data line A′ and the data line B are disposed between a first column of pixel cells and a second column of pixel cells. Each pixel cell may be defined by two central lines. According to an embodiment of the invention, the central lines may be an extending line which is a virtual line correspondingly positioned between a pair of data lines that are closest to each other. Distances from the extending line to each one of the pair of data lines alone the horizontal direction are substantially the same, such as the central lines Center_1, Center_2, Center_3, . . . Center 10 shown in FIG. 3A.

It should be noted that in the embodiment of the disclosure, the configurations of the pixel cells and the data lines may be spatially overlapped (for example, the vertical projections of the pixel cells and the data lines may be completely or partially overlapped), or may not completely overlap in space (for example, two data lines may be disposed between two pixel cells or between two columns of pixel cells, and the data lines and the pixel cells do not completely overlap in space).

On the other hand, according to an embodiment of the disclosure, a pair of adjacent data lines, such as the data line A and the data line A′, may be disposed on one pixel cell or one column of pixel cells. For example, as shown in FIG. 2, the data lines A and A′ and the first column of pixel cells may be spatially overlapped. In the embodiment of the disclosure, when the pixel cell and the data line are configured to be spatially overlapped, an insulating layer may be optionally provided between the pixel electrode of the pixel cell and the data line. The insulating layer may be an organic material or an inorganic material, so as to reduce the coupling capacitance between the pixel electrode and the data line.

According to an embodiment of the disclosure, the pixel cells arranged in a vertical direction in the pixel array (that is, a column of pixel cells) may comprise the pixel cells configured to display different colors, and the pixel cells arranged in a horizontal direction in the pixel array (that is, a row of pixel cells) may also comprise the pixel cells configured to display different colors. In the embodiments of the disclosure, based on different optical requirements, there may be a variety of different arrangements for the pixel cells and the data lines. In the following paragraphs, several embodiments of different arrangements for the pixel cells and the data lines will be illustrated. It should be noted that the embodiments described below are just some of a variety of embodiments that can be achieved by the disclosure, that is, the disclosure is not limited to the arrangements shown in the embodiments.

In addition, since each data line is coupled to the pixel cells configured to display the same color, in different embodiments of the disclosure, the data line may be coupled to adjacent pixel cells, or may be not coupled to the adjacent pixel cells. When the data line is coupled to one pixel cell, the arrows shown in FIG. 2 represent the directions of image data provided to the pixel cell. Therefore, in FIG. 2 and other figures of the disclosure, the direction of the arrow represents the direction of the data flow of the image data provided by the corresponding data line. In the embodiment of the disclosure, if there is a fourth data line disposed between the third data line and the pixel cells coupled to the third data line, the coupling between the third data line and the pixel cells may be implemented through the contact via and the connecting conductor in such a manner as to cross the fourth data line. The connecting conductor may be a conductive material such as metal, metal oxide or conductive polymer, but the disclosure should not be limited thereto. It should be noted that the use of ordinal terms such as “first”, “second”, etc., above does not by itself connote any specific direction or order arrangement in space.

According to an embodiment of the disclosure, a pair of adjacent data lines may be coupled to the display cells configured to display the same color, for providing the image data to the corresponding pixel cells, and a pair of adjacent data lines may be configured to provide image data having opposite voltage polarities, so as to solve the crosstalk problem.

In addition, in the embodiments of the disclosure, based on different optical requirements, there may be a variety of different pixel cells and data lines arrangements. Therefore, in the embodiments of the disclosure, the pixel cells arranged in a vertical direction in the pixel array (that is, a column of pixel cells) may comprise the pixel cells configured to display different colors, and the pixel cells disposed in a horizontal direction in the pixel array (that is, a row of pixel cells) may also comprise the pixel cells configured to display different colors.

It should be noted that for simplicity, the scan lines are not shown in the figures in the following embodiments.

FIG. 3A shows the exemplary pixel cell arrangement according to a first embodiment of the disclosure. In the embodiments of the disclosure, the coding scheme of the pixel cells is “color-X-Y”, where the color represents the color configured to be displayed by the corresponding pixel cell, such as the red (R), green (G) and blue (B), the X represents the index of the gate line (scan line), and the Y represents the index of the data line. It should be noted that in the first embodiment of the disclosure, the index of the data line DL_B+ coupled to the blue pixel cell in the leftmost is set to 0.

In the embodiment of the disclosure, a width to height ratio (aspect ratio) of the pixel cell may be greater than 1. That is, when designing the size of the pixel cell, it may arrange the width W of the pixel cells in a horizontal direction (such as the X axis) greater than a height H of the pixel cells in a vertical direction (such as the Y axis). For example, in an embodiment of the disclosure, a width-to-height ratio of the pixel cell may be 2:1.5. However, it should be noted that the width-to-height ratio of the pixel cell may also be properly adjusted according to the size of the display panel. Therefore, the implementation of the disclosure is not limited to the width-to-height ratio of 2:1.5, and the width Win the horizontal direction is not limited to be greater than the height H in the vertical direction. In addition, in the embodiment of the disclosure, the definition of the horizontal direction is substantially the main extension direction of the scan lines, and the definition of the width in the horizontal direction is substantially equal to the “fixed pitch” of the pixel electrodes when multiple pixel cells are arranged in the horizontal direction. The definition of the vertical direction is substantially the direction perpendicular to the main extension direction of the scan lines, or is substantially the main extension direction of the data lines. The definition of the height in the vertical direction is substantially equal to the “fixed pitch” of the pixel electrodes when multiple pixel cells are arranged in the vertical direction.

As shown in the figure, in this embodiment, the pixel cells may comprise a plurality of columns of pixel cells, the data lines DL_R+ and DL_R− may be the data lines coupled to the red pixel cells, the data lines DL_G+ and DL_G− may be the data lines coupled to the green pixel cells, and the data lines DL_B+ and DL_B− may be the data lines coupled to the blue pixel cells, where the positive sign ‘+’ indicates that the voltage of the image data signal supplied by the data line is positive with respect to the common voltage VCOM, and the negative sign ‘−’ indicates that the voltage of the image data signal supplied by the data line is negative with respect to the common voltage VCOM. In other words, the positive sign indicates that the voltage of the image data signal supplied by the data line is greater than the common voltage VCOM, and the negative sign indicates that the voltage of the image data signal supplied by the data line is smaller than the common voltage VCOM.

In this embodiment, the adjacent two data lines DL_R+ and DL_R− may be regarded as a pair of data lines, the adjacent two data lines DL_G+ and DL_G− may be regarded as a pair of data lines, and the adjacent two data lines DL_B+ and DL_B− may be regarded as a pair of data lines. According to an embodiment of the disclosure, each pair of adjacent data lines may be coupled to the pixel cells configured to display the same color, and may be configured to provide the image data to the corresponding pixel cells.

In addition, in this embodiment, a pair of adjacent data lines are configured to provide image data having opposite voltage polarities.

In addition, in this embodiment, the polarity inversion method for driving each pixel cell may comprise various methods, such as the dot inversion, the column inversion, the line inversion, etc. The disclosure is not limited to any specific type of polarity inversion method.

In addition, in this embodiment, at least two data lines are disposed between two adjacent pixel cells or two adjacent columns of pixel cells. For example, the data lines DL_B− and DL_G− are disposed between adjacent pixel cells R-1-1 and B-1-1, where the pixel cells R-1-1 and B-1-1 are configured to display different colors.

It should be noted that in the embodiment of the disclosure, the configurations of the pixel cells and the data lines may be spatially overlapped as shown in the figures, for example, the vertical projections of the pixel cells and the data lines may be completely or partially overlapped, or the configurations of the pixel cells and the data lines may not completely overlap in space.

On the other hand, in an embodiment of the disclosure, a pair of adjacent data lines may also be disposed on one pixel cell or one column of pixel cells. For example, as shown in FIG. 3A, the data lines DL_B+ and DL_B− may be disposed on pixel cell R-1-1 or disposed on the first column of pixel cells that comprising the pixel cell R-1-1, and the data lines and the pixel cells may be spatially overlapped as shown in FIG. 3A.

In addition, in the embodiments of the disclosure, the pixel cells arranged along a vertical direction in the pixel array (for example, a column of pixel cells) may comprise the pixel cells for displaying different colors. The pixel cells arranged along a horizontal direction in the pixel array (for example, a row of pixel cells) may also comprise pixel cells for displaying different colors.

According to a first embodiment of the disclosure, the multiple data lines may comprise multiple first data lines and multiple second data lines, and the multiple first data lines may be coupled to a part of multiple pixel cells (e.g. the first pixel cells) in the pixel array. The multiple second data lines may comprise a third data line and a fourth data line adjacent to the third data line. The third data line is disposed adjacent to a side of a first boundary of a first column of pixel cells, the fourth data line is disposed adjacent to a side of a second boundary of the first column of pixel cells. The third data line is coupled to a part of multiple pixel cells that are configured to display the same color in a second column of pixel cells for providing image data to the corresponding pixel cells, where the second column of pixel cells are adjacent to the first boundary of the first column of pixel cells. The fourth data line is coupled to another part of the multiple pixel cells that are configured to display the same color in a third column of pixel cells for providing image data to the corresponding pixel cells, where the third column of pixel cells are adjacent to the second boundary of the first column of pixel cells.

In an embodiment, the multiple pixel cells may comprise multiple first pixel cells and multiple second pixel cells. The multiple data lines may comprise multiple first data lines and multiple second data lines. One of the multiple first data lines is coupled to the multiple first pixel cells which are configured to display color(s) different from the color of the multiple second pixel cells. One of the multiple first data lines can be coupled to the multiple first pixel cells in the pixel array.

It should be noted that the use of ordinal terms such as “first”, “second”, etc., above does not by itself connote any specific direction or order arrangement in space.

For example, the data line DL_G− may be disposed adjacent to the left hand side of the second column of pixel cells in FIG. 3A (for example, comprising the pixel cells B-1-1, R-1-1, R-2-2, B-2-1, B-3-1 . . . etc.), the data line DL_G+ may be disposed adjacent to the right hand side of the second column of pixel cells. The data line DL_G− may be coupled to the pixel cells configured to display the green color (for example, the pixel cells G-1-1, G-2-1, G-3-1, G-4-1 . . . etc.) in the first column of pixel cells which is adjacent to the left hand side boundary of the second column of pixel cells, for providing image data to the corresponding pixel cells. The data line DL_G+ may be coupled to the pixel cells configured to display the green color (for example, the pixel cells G-1-2, G-2-2, G-3-2, G-4-2 . . . etc.) in the third column of pixel cells which is adjacent to the right hand side boundary of the second column of pixel cells, for providing image data to the corresponding pixel cells. The direction of the arrows shown in FIG. 3A represents the direction of the data flow of the image data provided by the corresponding data line.

FIG. 3B is a schematic diagram showing the voltage polarity of the image data signal to be provided to each pixel cell according to a first embodiment of the disclosure. The positive sign ‘+’ indicates that the voltage of the image data signal received by the pixel cell is positive with respect to the common voltage VCOM, and the negative sign ‘−’ indicates that the voltage of the image data signal received by the pixel cell is negative with respect to the common voltage VCOM. According to an embodiment of the disclosure, when arranging the pixel cells displaying different colors, a minimum unit may be defined. For example, the minimum array unit 250 shown in FIG. 3B.

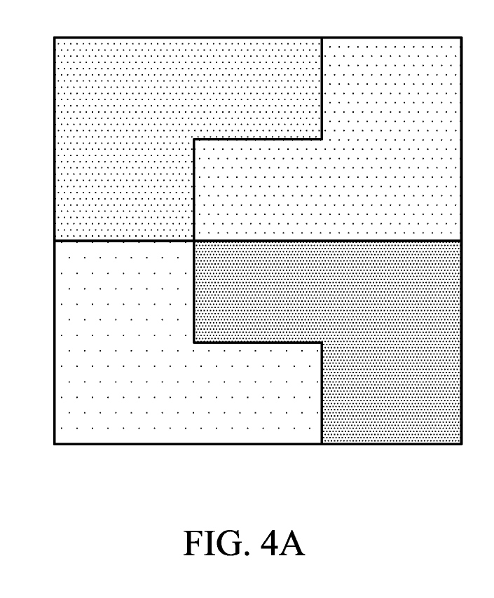

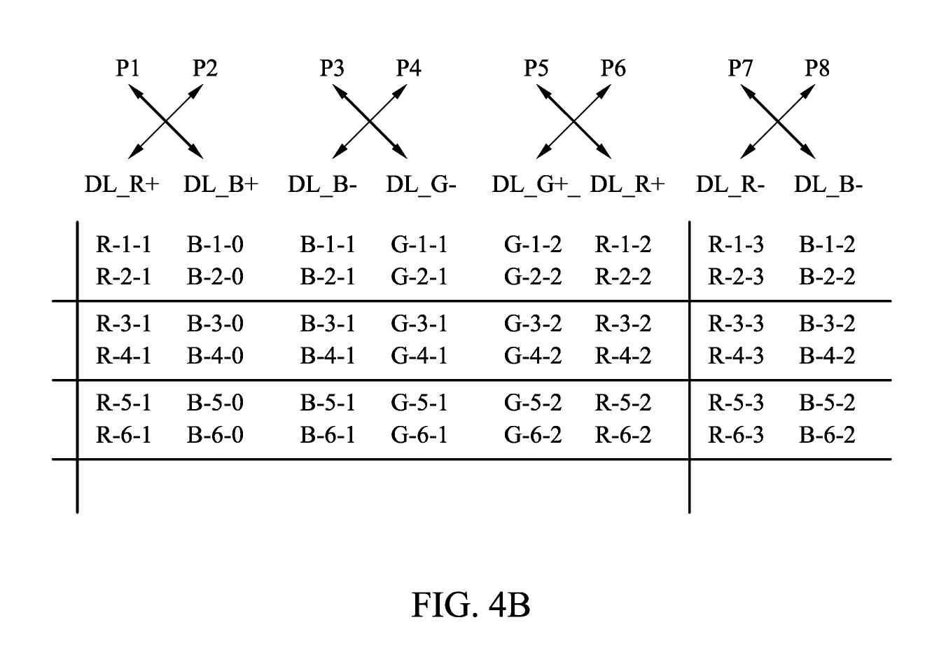

FIG. 4A is a schematic diagram showing the minimum array unit according to the first embodiment of the disclosure. As shown in this figure, the pixel cells corresponding to a set of RGB sub-pixels may form an L-shape pixel, and four L-shape pixels form the minimum array unit of the first embodiment. Based on resolution requirements, there may be a plurality of such minimum array units repeatedly arranged in the pixel array, so as to form the pixel array having a specific resolution. However, it should be noted that in the disclosure, the total number of pixel cells in the pixel array is not limited to be a multiple of the total number of pixel cells in the minimum array unit. That is, in addition to repeatedly arranging a plurality of such minimum matrix units, different numbers of pixel cells may also be added in the pixel array based on the optical requirement.

FIG. 4B is a schematic diagram showing the coupling relationship of the data lines and the pixel cells in the active area of the display panel and the output pins of the data driver chip according to the first embodiment of the disclosure. The output pins of the data driver chip may comprise the pins P1, P2 . . . P8, and the data signal output by each output pin is arranged in order of red(R)->green(G)->blue(B)->red(R)->green(G)->blue(B). As shown in the figure, in the embodiment of the disclosure, in order to implement the pixel cell configuration as illustrated above, the data lines in the active area of the display panel are not arranged in order of red(R)->green(G)->blue(B). Therefore, in the embodiment of the disclosure, the coupling of the output pins of the data driver chip and the data lines may have a cross-over structure, such as the two staggered arrows shown in the figure. By using the cross-over structure, the order of the output data signal may be restored to the order of red(R)->green(G)->blue(B). It should be noted that if the output pins of the data driver chip are customized and arranged in the same order as the data lines of the disclosure, there is no need to connect them in a cross-over manner.

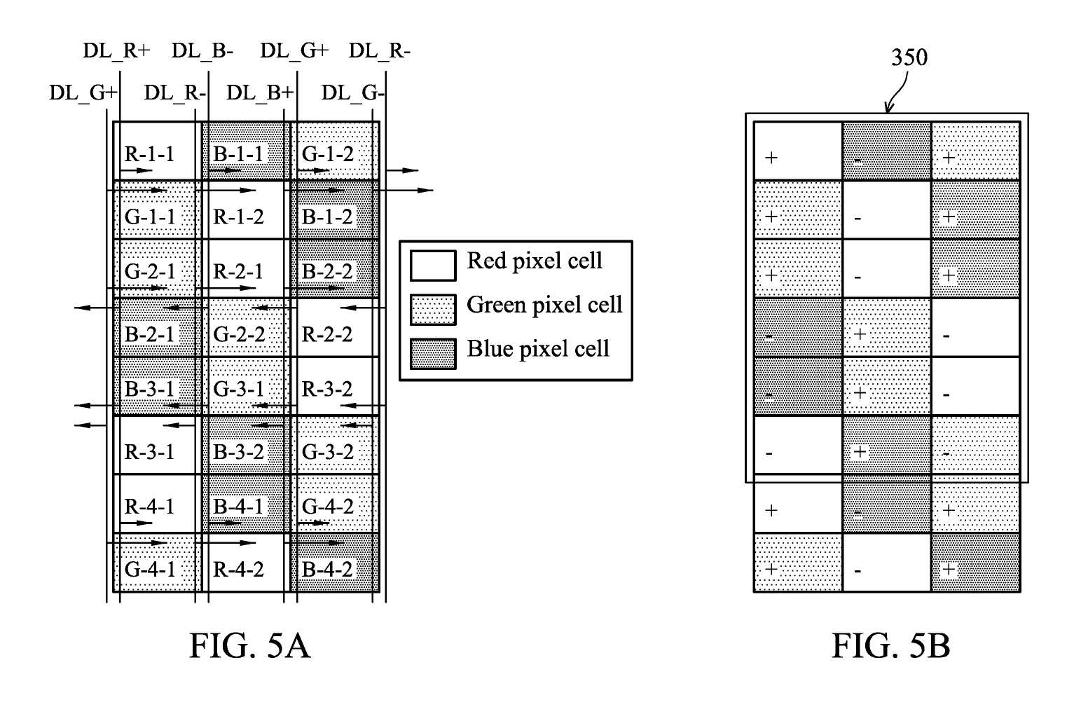

FIG. 5A shows the exemplary pixel cell arrangement according to a second embodiment of the disclosure. In the embodiments of the disclosure, the width-to-height ratio of the pixel cell may be greater than 1. That is, when designing the size of the pixel cell, it may arrange the width of the pixel cells in a horizontal direction (such as the X axis) greater than a height of the pixel cells in a vertical direction (such as the Y axis). For example, in an embodiment of the disclosure, a width-to-height ratio of the pixel cell may be 2:1.5. However, it should be noted that the width-to-height ratio of the pixel cell may also be properly adjusted according to the size of the display panel. Therefore, the implementation of the disclosure is not limited to the width-to-height ratio of 2:1.5, and the width in the horizontal direction is not limited to be greater than the height in the vertical direction.

In this embodiment, the two adjacent data lines DL_R+ and DL_R− may be regarded as a pair of data lines, the two adjacent data lines DL_G+ and DL_G− may be regarded as a pair of data lines, and the two adjacent data lines DL_B+ and DL_B− may be regarded as a pair of data lines. In an embodiment of the disclosure, each pair of adjacent data lines may be coupled to the pixel cells configured to display the same color, for providing image data to the corresponding pixel cells.

In addition, in this embodiment, a pair of adjacent data lines are configured to provide image data having opposite voltage polarities.

In addition, in this embodiment, the polarity inversion method for driving each pixel cell may comprise various methods, such as the dot inversion, the column inversion, the line inversion, etc. The disclosure is not limited to any specific type of polarity inversion method.

In addition, in this embodiment, at least two data lines are disposed between two adjacent pixel cells or two adjacent columns of pixel cells. For example, the data lines DL_R− and DL_B− are disposed between adjacent pixel cells R-1-1 and B-1-1, where the pixel cells R-1-1 and B-1-1 are configured to display different colors.

It should be noted that in the embodiment of the disclosure, the configurations of the pixel cells and the data lines may be spatially overlapped as shown in the figures, for example, the vertical projections of the pixel cells and the data lines may be completely or partially overlapped, or the configurations of the pixel cells and the data lines may not completely overlap in space.

On the other hand, in an embodiment of the disclosure, a pair of adjacent data lines may also be disposed on one pixel cell or one column of pixel cells. For example, as shown in FIG. 5A, the data lines DL_R+ and DL_R− may be disposed on pixel cell R-1-1 or disposed on the first column of pixel cells that comprising the pixel cell R-1-1, and the data lines and the pixel cells may be spatially overlapped as shown in FIG. 5A.

In the embodiments of the disclosure, the pixel cells arranged along a vertical direction in the pixel array (for example, a column of pixel cells) may comprise the pixel cells for displaying different colors. The pixel cells arranged along a horizontal direction in the pixel array (for example, a row of pixel cells) may also comprise pixel cells for displaying different colors.

According to the second embodiment of the disclosure, a third data line is disposed adjacent to a side of a first boundary of a first column of pixel cells, a fourth data line is disposed adjacent to a side of a second boundary of the first column of pixel cells. One of the third data line and the fourth data line is coupled to the pixel cells that are configured to display the same color in a first column of pixel cells for providing image data to the corresponding pixel cells.

It should be noted that the use of ordinal terms such as “first”, “second”, etc., above does not by itself connote any specific direction or order arrangement in space.

For example, the data line DL_B− may be disposed adjacent to the left hand side of the second column of pixel cells (for example, comprising the pixel cells B-1-1, R-1-2, R-2-1, G-2-2, G-3-1 . . . etc.), the data line DL_B+ may be disposed adjacent to the right hand side of the second column of pixel cells. Only one of the data lines DL_B− and DL_B+ (for example, the data lines DL_B−) may be coupled to the pixel cells configured to display the blue color (for example, the pixel cells B-1-1, B-4-1 . . . etc.) in the second column of pixel cells, for providing image data to the corresponding pixel cells. The data line DL_B+ may be coupled to the pixel cells configured to display the blue color (for example, the pixel cells B-1-2, B-2-2, B-4-2 . . . etc.) in the third column of pixel cells, for providing image data to the corresponding pixel cells.

FIG. 5B is a schematic diagram showing the voltage polarity of the image data signal to be provided to each pixel cell according to a second embodiment of the disclosure. The positive sign ‘+’ indicates that the voltage of the image data signal received by the pixel cell is positive with respect to the common voltage VCOM, and the negative sign ‘−’ indicates that the voltage of the image data signal received by the pixel cell is negative with respect to the common voltage VCOM. In the embodiments of the disclosure, when arranging the pixel cell displaying different colors, a minimum unit may be defined. For example, the minimum array unit 350 shown in FIG. 5B. Based on resolution requirements, there may be a plurality of such minimum array units 350 repeatedly arranged in the pixel array, so as to form the pixel array having a specific resolution.

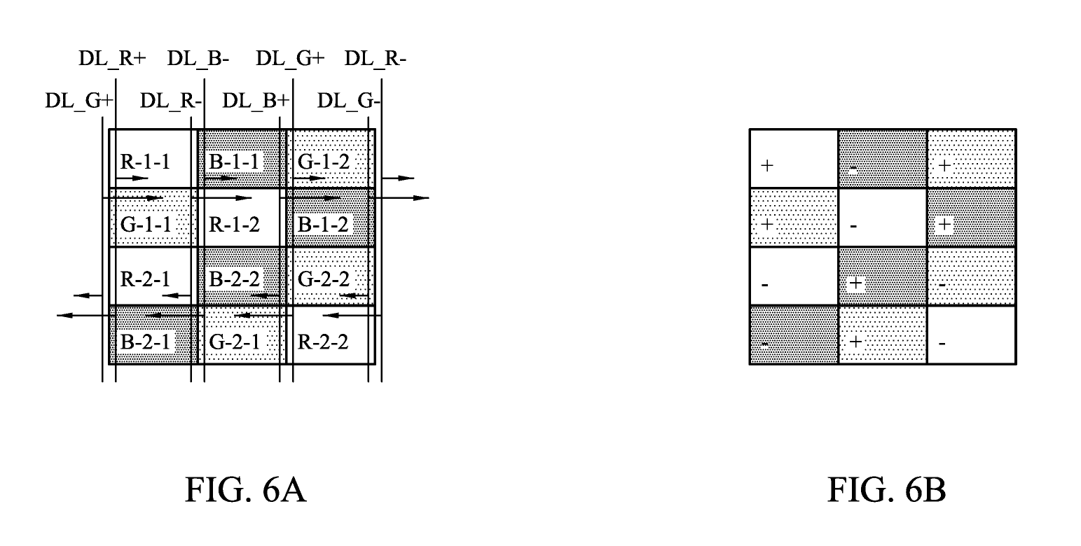

FIG. 6A shows the exemplary pixel cell arrangement according to a third embodiment of the disclosure. In the embodiments of the disclosure, the width-to-height ratio of the pixel cell may be greater than 1. That is, when designing the size of the pixel cell, it may arrange the width of the pixel cells in a horizontal direction (such as the X axis) greater than a height of the pixel cells in a vertical direction (such as the Y axis). For example, in an embodiment of the disclosure, a width-to-height ratio of the pixel cell may be 2:1.5. However, it should be noted that the width-to-height ratio of the pixel cell may also be properly adjusted according to the size of the display panel. Therefore, the implementation of the disclosure is not limited to the width-to-height ratio of 2:1.5, and the width Win the horizontal direction is not limited to be greater than the height H in the vertical direction.

In this embodiment, the two adjacent data lines DL_R+ and DL_R− may be regarded as a pair of data lines, the two adjacent data lines DL_G+ and DL_G− may be regarded as a pair of data lines, and the two adjacent data lines DL_B+ and DL_B− may be regarded as a pair of data lines. In an embodiment of the disclosure, each pair of adjacent data lines may be coupled to the pixel cells configured to display the same color, for providing image data to the corresponding pixel cells.

In addition, in this embodiment, a pair of adjacent data lines are configured to provide image data having opposite voltage polarities.

In addition, in this embodiment, the polarity inversion method for driving each pixel cell may comprise various methods, such as the dot inversion, the column inversion, the line inversion, etc. The disclosure is not limited to any specific type of polarity inversion method.

In addition, in this embodiment, at least two data lines are disposed between two adjacent pixel cells or two adjacent columns of pixel cells. For example, the data lines DL_R− and DL_B− are disposed between adjacent pixel cells R-1-1 and B-1-1, where the pixel cells R-1-1 and B-1-1 are configured to display different colors.

It should be noted that in the embodiment of the disclosure, the configurations of the pixel cells and the data lines may be spatially overlapped as shown in the figures, for example, the vertical projections of the pixel cells and the data lines may be completely or partially overlapped, or the configurations of the pixel cells and the data lines may not completely overlap in space.

On the other hand, in an embodiment of the disclosure, a pair of adjacent data lines may also be disposed on one pixel cell or one column of pixel cells. For example, as shown in FIG. 6A, the data lines DL_R+ and DL_R− may be disposed on pixel cell R-1-1 or disposed on the first column of pixel cells that comprising the pixel cell R-1-1, and the data lines and the pixel cells may be spatially overlapped as shown in FIG. 6A.

In the embodiments of the disclosure, the pixel cells arranged along a vertical direction in the pixel array (for example, a column of pixel cells) may comprise the pixel cells for displaying different colors. The pixel cells arranged along a horizontal direction in the pixel array (for example, a row of pixel cells) may also comprise pixel cells for displaying different colors.

According to a third embodiment of the disclosure, a third data line is disposed adjacent to a side of a first boundary of a first column of pixel cells, a fourth data line is disposed adjacent to a side of a second boundary of the first column of pixel cells. The third data line and the fourth data line are coupled to the pixel cells that are configured to display the same color in the first column of pixel cells, for providing image data to the corresponding pixel cells.

It should be noted that the use of ordinal terms such as “first”, “second”, etc., above does not by itself connote any specific direction or order arrangement in space.

For example, the data line DL_B− may be disposed adjacent to the left hand side of the second column of pixel cells (for example, the pixel cells B-1-1, R-1-2, B-2-2, G-2-1 . . . etc.), the data line DL_B+ may be disposed adjacent to the right hand side of the second column of pixel cells. The data lines DL_B− and DL_B+ may be respectively coupled to the pixel cells configured to display the blue color (for example, the pixel cells B-1-1, B-2-2 . . . etc.) in the second column of pixel cells, for providing image data to the corresponding pixel cells.

FIG. 6B is a schematic diagram showing the voltage polarity of the image data signal to be provided to each pixel cell according to a third embodiment of the disclosure. The positive sign ‘+’ indicates that the voltage of the image data signal received by the pixel cell is positive with respect to the common voltage VCOM, and the negative sign ‘−’ indicates that the voltage of the image data signal received by the pixel cell is negative with respect to the common voltage VCOM. In the embodiments of the disclosure, when arranging the pixel cell displaying different colors, a minimum unit may be defined. For example, the minimum array unit shown in FIG. 6B. Based on resolution requirements, there may be a plurality of such minimum array units repeatedly arranged in the pixel array, so as to form the pixel array having a specific resolution.

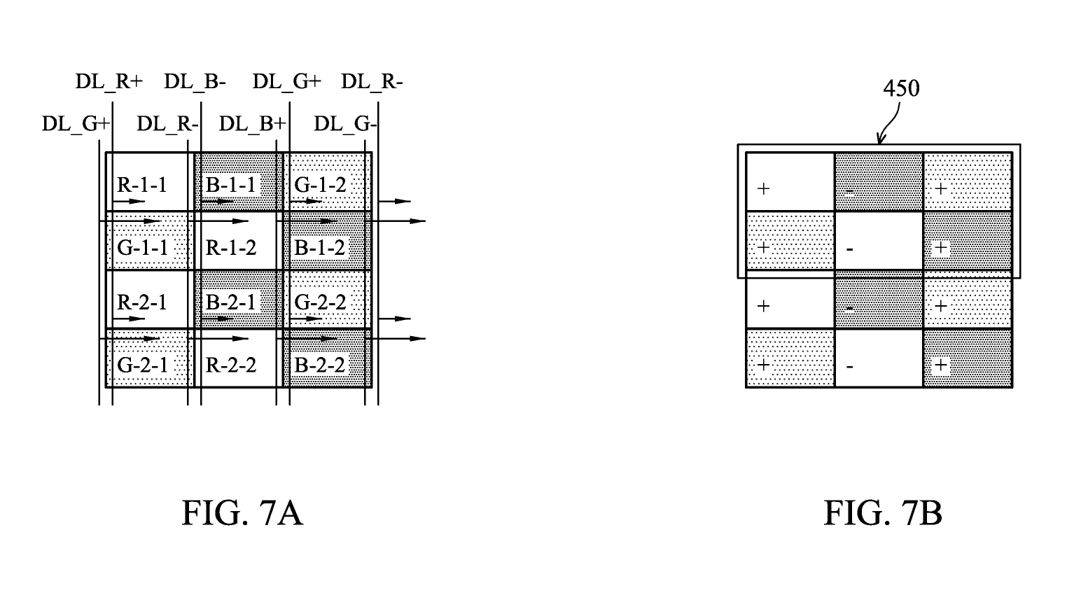

FIG. 7A shows the exemplary pixel cell arrangement according to a fourth embodiment of the disclosure. In the embodiments of the disclosure, the width-to-height ratio of the pixel cell may be greater than 1. That is, when designing the size of the pixel cell, it may arrange the width of the pixel cells in a horizontal direction (such as the X axis) greater than a height of the pixel cells in a vertical direction (such as the Y axis). For example, in an embodiment of the disclosure, a width-to-height ratio of the pixel cell may be 2:1.5. However, it should be noted that the width-to-height ratio of the pixel cell may also be properly adjusted according to the size of the display panel. Therefore, the implementation of the disclosure is not limited to the width-to-height ratio of 2:1.5, and the width in the horizontal direction is not limited to be greater than the height in the vertical direction.

In this embodiment, the two adjacent data lines DL_R+ and DL_R− may be regarded as a pair of data lines, the two adjacent data lines DL_G+ and DL_G− may be regarded as a pair of data lines, and the two adjacent data lines DL_B+ and DL_B− may be regarded as a pair of data lines. In an embodiment of the disclosure, each pair of adjacent data lines may be coupled to the pixel cells configured to display the same color, for providing image data to the corresponding pixel cells.

In addition, in this embodiment, a pair of adjacent data lines are configured to provide image data having opposite voltage polarities.

In addition, in this embodiment, the polarity inversion method for driving each pixel cell may comprise various methods, such as the dot inversion, the column inversion, the line inversion, etc. The disclosure is not limited to any specific type of polarity inversion method.

In addition, in this embodiment, at least two data lines are disposed between two adjacent pixel cells or two adjacent columns of pixel cells. For example, the data lines DL_R− and DL_B− are disposed between adjacent pixel cells R-1-1 and B-1-1, where the pixel cells R-1-1 and B-1-1 are configured to display different colors.

It should be noted that in the embodiment of the disclosure, the configurations of the pixel cells and the data lines may be spatially overlapped as shown in the figures, for example, the vertical projections of the pixel cells and the data lines may be completely or partially overlapped, or the configurations of the pixel cells and the data lines may not completely overlap in space.

On the other hand, in an embodiment of the disclosure, a pair of adjacent data lines may also be disposed on one pixel cell or one column of pixel cells. For example, as shown in FIG. 7A, the data lines DL_R+ and DL_R− may be disposed on pixel cell R-1-1 or disposed on the first column of pixel cells that comprising the pixel cell R-1-1, and the data lines and the pixel cells may be spatially overlapped as shown in FIG. 7A.

In the embodiments of the disclosure, the pixel cells arranged along a vertical direction in the pixel array (for example, a column of pixel cells) may comprise the pixel cells for displaying different colors. The pixel cells arranged along a horizontal direction in the pixel array (for example, a row of pixel cells) may also comprise pixel cells for displaying different colors.

According to a fourth embodiment of the disclosure, a third data line is disposed adjacent to a side of a first boundary of a first column of pixel cells, a fourth data line is disposed adjacent to a side of a second boundary of the first column of pixel cells. One of the third data line and the fourth data line is coupled to the pixel cells that are configured to display the same color in the first column of pixel cells, for providing image data to the corresponding pixel cells.

It should be noted that the use of ordinal terms such as “first”, “second”, etc., above does not by itself connote any specific direction or order arrangement in space.

For example, the data line DL_B− may be disposed adjacent to the left hand side of the second column of pixel cells (for example, comprising the pixel cells B-1-1, R-1-2, B-2-1, R-2-2 . . . etc.), the data line DL_B+ may be disposed adjacent to the right hand side of the second column of pixel cells. One of the data lines DL_B− and DL_B+(for example, the data lines DL_B−) may be coupled to the pixel cells configured to display the blue color (for example, the pixel cells B-1-1, B-2-1 . . . etc.) in the second column of pixel cells, for providing image data to the corresponding pixel cells. The data line DL_B+ may be coupled to the pixel cells configured to display the blue color (for example, the pixel cells B-1-2, B-2-2 . . . etc.) in the third column of pixel cells, for providing image data to the corresponding pixel cells.

FIG. 7B is a schematic diagram showing the voltage polarity of the image data signal to be provided to each pixel cell according to a fourth embodiment of the disclosure. The positive sign ‘+’ indicates that the voltage of the image data signal received by the pixel cell is positive with respect to the common voltage VCOM, and the negative sign ‘−’ indicates that the voltage of the image data signal received by the pixel cell is negative with respect to the common voltage VCOM. In the embodiments of the disclosure, when arranging the pixel cell displaying different colors, a minimum unit may be defined. For example, the minimum array unit 450 shown in FIG. 7B. Based on resolution requirements, there may be a plurality of such minimum array units repeatedly arranged in the pixel array, so as to form the pixel array having a specific resolution.

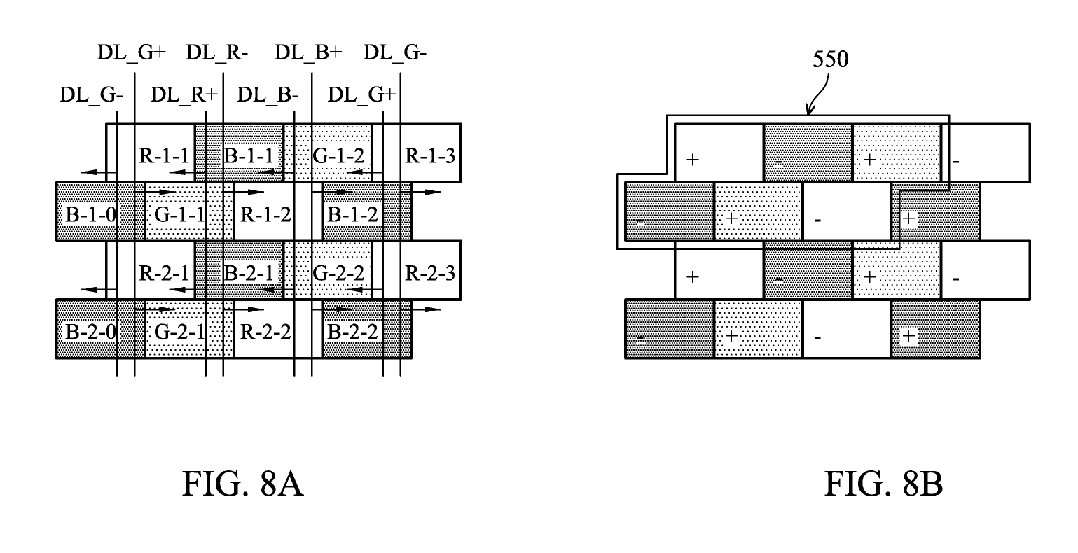

FIG. 8A shows the exemplary pixel cell arrangement according to a fifth embodiment of the disclosure. In the embodiments of the disclosure, the width-to-height ratio of the pixel cell may be greater than 1. That is, when designing the size of the pixel cell, it may arrange the width of the pixel cells in a horizontal direction (such as the X axis) greater than a height of the pixel cells in a vertical direction (such as the Y axis). For example, in an embodiment of the disclosure, a width-to-height ratio of the pixel cell may be 2:1.5. However, it should be noted that the width-to-height ratio of the pixel cell may also be properly adjusted according to the size of the display panel. Therefore, the implementation of the disclosure is not limited to the width-to-height ratio of 2:1.5, and the width in the horizontal direction is not limited to be greater than the height in the vertical direction.

In this embodiment, the two adjacent data lines DL_R+ and DL_R− may be regarded as a pair of data lines, the two adjacent data lines DL_G+ and DL_G− may be regarded as a pair of data lines, and the two adjacent data lines DL_B+ and DL_B− may be regarded as a pair of data lines. In an embodiment of the disclosure, each pair of adjacent data lines may be coupled to the pixel cells configured to display the same color, for providing image data to the corresponding pixel cells.

In addition, in this embodiment, a pair of adjacent data lines are configured to provide image data having opposite voltage polarities.

In addition, in this embodiment, the polarity inversion method for driving each pixel cell may comprise various methods, such as the dot inversion, the column inversion, the line inversion, etc. The disclosure is not limited to any specific type of polarity inversion method.

In the embodiment of the disclosure, the pixel cells arranged along a vertical direction in the pixel array may comprise the pixel cells for displaying different colors. The pixel cells arranged along a horizontal direction in the pixel array may also comprise pixel cells for displaying different colors.

In the fifth embodiment of the disclosure, the boundaries of the pixel cells may be interleaved. For example, the boundaries of the pixel cells arranged along the vertical direction in the pixel array may be interleaved. In this embodiment, the positions of pixel cells in each row are adjusted horizontally to achieve a specific optical effect. That is, the application of the disclosure is not limited to the pixel array in which the boundaries of pixel cells are aligned, but also to the pixel array in which the boundaries of pixel cells are interleaved. It is to be noted that the distance of the adjustment in the boundary can be varied according to the optical effect to be achieved. In the embodiments of the disclosure, when arranging the pixel cells displaying different colors, a minimum unit may be defined. For example, the minimum array unit 550 shown in FIG. 8B. Based on resolution requirements, there may be a plurality of such minimum array units repeatedly arranged in the pixel array, so as to form the pixel array having a specific resolution.

As discussed above, in the embodiments of the disclosure, each data line is coupled to the pixel cells configured to display the same color, so as to solve the image distortion problem.

In addition, in the embodiments of the disclosure, a pair of adjacent data lines may be coupled to the display cells configured to display the same color, for providing the image data to the corresponding pixel cells, and a pair of adjacent data lines may be configured to provide image data having opposite voltage polarities, so as to solve the crosstalk problem.

In addition, in the embodiments of the disclosure, based on different optical requirements, there may be a variety of different arrangements for the pixel cells and the data lines, wherein the pixel cells arranged along a vertical direction in the pixel array may comprise the pixel cells for displaying different colors. The pixel cells arranged along a horizontal direction in the pixel array may also comprise pixel cells for displaying different colors.

Use of ordinal terms such as “first”, “second”, etc., in the claims to modify a claim element does not by itself connote any priority, precedence, or order of one claim element over another or the temporal order in which acts of a method are performed, but are used merely as labels to distinguish one claim element having a certain name from another element having the same name (but for use of the ordinal term) to distinguish the claim elements.

While the disclosure has been described by way of example and in terms of several embodiments, it is to be understood that the disclosure is not limited thereto. Those who are skilled in this technology can still make various alterations and modifications without departing from the scope and spirit of this disclosure. Therefore, the scope of the present disclosure shall be defined and protected by the following claims and their equivalents.

What is claimed is:

1. A display panel, comprising:
a pixel array, comprising multiple pixel cells; and
multiple data lines, coupled to the pixel array,
wherein the multiple pixel cells comprise multiple first pixel cells and multiple second pixel cells,
wherein the multiple data lines comprise multiple first data lines and multiple second data lines,
wherein one of the multiple first data lines is coupled to the multiple first pixel cells in the pixel array, and
wherein the multiple second data lines comprise a third data line and a fourth data line adjacent to the third data line, wherein a part of the multiple second pixel cells coupled to the third data line and another part of the multiple second pixel cells coupled to the fourth data line are configured to display the same color.

2. The display panel as claimed in claim 1, wherein the multiple first pixel cells are configured to display the same color in the pixel array.

3. The display panel as claimed in claim 1, wherein an image data provided by the third data line and an image data provided by the fourth data line have opposite voltage polarities.

4. The display panel as claimed in claim 1, wherein one of the multiple second pixel cells is adjacent to one of the multiple first pixel cells, wherein at least two data lines of the multiple data lines are disposed between the one of the multiple first pixel cells and the one of the multiple second pixel cells.

5. The display panel as claimed in claim 4, wherein the multiple first pixel cells are configured to display a first color, the multiple second pixel cells are configured to display a second color, and the first color and the second color are different.

6. The display panel as claimed in claim 1, wherein a width of one of the multiple pixel cells in a horizontal direction is greater than a height of the one of the multiple pixel cells in a vertical direction, and wherein the horizontal direction is perpendicular to a main extension direction of the data lines.

7. The display panel as claimed in claim 1, wherein the third data line and the fourth data line are disposed on one of the multiple second pixel cells, and a projection of the third data line and a projection of the fourth data line in a direction overlap a projection of the one of the multiple second pixel cells in the direction.

8. The display panel as claimed in claim 1, wherein the multiple pixel cells further comprises a first column of the multiple pixel cells, a second column of the multiple pixel cells, and a third column of the multiple pixel cells, the third data line is disposed adjacent to a side of a first boundary of the first column of the multiple pixel cells, the fourth data line is disposed adjacent to a side of a second boundary of the first column of the multiple pixel cells, and the third data line is coupled to a part of the second column of the multiple pixel cells which are adjacent to the first boundary of the first column of the multiple pixel cells, and the fourth data line is coupled to a part of the third column of the multiple pixel cells which are adjacent to the second boundary of the first column of the multiple pixel cells.

9. The display panel as claimed in claim 1, wherein the multiple pixel cells further comprises a first column of the multiple pixel cells, the third data line is disposed adjacent to a side of a first boundary of the first column of the multiple pixel cells, the fourth data line is disposed adjacent to a side of a second boundary of the first column of the multiple pixel cells, and the third data line or the fourth data line is coupled to a part of the first column of the multiple pixel cells.

10. The display panel as claimed in claim 1, wherein the multiple pixel cells further comprises a first column of the multiple pixel cells, the third data line is disposed adjacent to a side of a first boundary of the first column of the multiple pixel cells, the fourth data line is disposed adjacent to a side of a second boundary of the first column of the multiple pixel cells, and the third data line and the fourth data line are coupled to a part of the first column of the multiple pixel cells.

11. A display device, comprising:
a display panel, comprising a pixel array and multiple data lines coupled to the pixel array; and
a data driving circuit, configured to generate multiple data driving signals to provide image data to the pixel array via the multiple data lines,
wherein the pixel array comprises multiple pixel cells,
wherein the multiple pixel cells comprise multiple first pixel cells and multiple second pixel cells,
wherein the multiple data lines comprise multiple first data lines and multiple second data lines,
wherein one of the multiple first data lines is coupled to the multiple first pixel cells in the pixel array, and
wherein the multiple second data lines comprise a third data line and a fourth data line adjacent to the third data line, wherein a part of the multiple second pixel cells coupled to the third data line and another part of the multiple second pixel cells coupled to the fourth data line are configured to display the same color.

12. The display device as claimed in claim 11, wherein the multiple first pixel cells are configured to display the same color in the pixel array.

13. The display device as claimed in claim 11, wherein the image data provided by the third data line and the image data provided by the fourth data line have opposite voltage polarities.

14. The display device as claimed in claim 11, wherein one of the multiple second pixel cells is adjacent to one of the multiple first pixel cells, wherein at least two data lines of the multiple data lines are disposed between the one of the multiple first pixel cells and the one of the multiple second pixel cells.

15. The display device as claimed in claim 14, wherein the multiple first pixel cells are configured to display a first color, the multiple second pixel cells are configured to display a second color, and the first color and the second color are different.

16. The display device as claimed in claim 11, wherein a width of one of the multiple pixel cells in a horizontal direction is greater than a height of the one of the multiple pixel cells in a vertical direction, and wherein the horizontal direction is perpendicular to a main extension direction of the data lines.

17. The display device as claimed in claim 11, wherein the third data line and the fourth data line are disposed on one of the multiple second pixel cells, and a projection of the third data line and a projection of the fourth data line in a direction overlap a projection of the one of the multiple second pixel cells in the direction.

18. The display device as claimed in claim 11, wherein the multiple pixel cells further comprises a first column of the multiple pixel cells, a second column of the multiple pixel cells, and a third column of the multiple pixel cells, the third data line is disposed adjacent to a side of a first boundary of the first column of the multiple pixel cells, the fourth data line is disposed adjacent to a side of a second boundary of the first column of the multiple pixel cells, and the third data line is coupled to a part of the second column of the multiple pixel cells which are adjacent to the first boundary of the first column of the multiple pixel cells, and the fourth data line is coupled to a part of the third column of the multiple pixel cells which are adjacent to the second boundary of the first column of the multiple pixel cells.

19. The display device as claimed in claim 11, wherein the multiple pixel cells further comprises a first column of the multiple pixel cells, the third data line is disposed adjacent to a side of a first boundary of the first column of the multiple pixel cells, the fourth data line is disposed adjacent to a side of a second boundary of the first column of the multiple pixel cells, and the third data line or the fourth data line is coupled to a part of the first column of the multiple pixel cells.

20. The display device as claimed in claim 11, wherein the multiple pixel cells further comprises a first column of the multiple pixel cells, the third data line is disposed adjacent to a side of a first boundary of the first column of the multiple pixel cells, the fourth data line is disposed adjacent to a side of a second boundary of the first column of the multiple pixel cells, and the third data line and the fourth data line are coupled to a part of the first column of the multiple pixel cells.
